(19) United States
(12) Patent Application Publication
(10) Pub. No.: US 2008/0009124 A1
(43) Pub. Date: Jan. 10, 2008

(54) Method of forming a semiconductor device

(76) Inventors: Masakazu Ishino, Tokyo (JP); Hiroaki Ikeda, Tokyo (JP)

Correspondence Address: SCULLY SCOTT MURPHY & PRESSER, PC, 400 GARDEN CITY PLAZA, SUITE 300, GARDEN CITY, NY, 11530, US

(21) Appl. No.: 11/824,626

(22) Filed: Jul. 2, 2007

(30) Foreign Application Priority Data
Jul. 7, 2006 (JP) P2006-188000

(51) Int. Cl. H01L 21/00

(52) U.S. Cl. 438/460

(57) ABSTRACT

A method of forming a semiconductor device includes the following processes. A semiconductor wafer including chips and through electrodes is diced into chip groups. The chip groups are stacked to form a module group.

### BACKGROUND OF THE INVENTION

1. Field of the Invention

The present invention generally relates to a method of forming a semiconductor device. More specifically, the present invention relates to a semiconductor device including a plurality of stacked chips, and a method of forming the semiconductor device.

Priority is claimed on Japanese Patent Application No. 2006-188000, filed Jul. 7, 2006, the content of which is incorporated herein by reference.

2. Description of the Related Art

All patents, patent applications, patent publications, scientific articles, and the like, which will hereinafter be cited or identified in the present application, will hereby be incorporated by reference in their entirety in order to describe more fully the state of the art to which the present invention pertains.

There has been known a semiconductor device that includes a plurality of stacked chips with through-electrodes. A typical example of the semiconductor device of this type may also be three dimensional LSIs. FIG. 1 is a schematic perspective view illustrating a three dimensional LSI. A three dimensional LSI module 104 includes an interposer substrate 105 and a plurality of stacked chips 101 that is provided on the interposer substrate 105. Each chip 101 has through-electrodes that provide electrical connections with an adjacent chip 101 so that the stacked chips 101 are electrically connected through the through-electrodes. Each chip 101 has a configuration of the unit that operates as a device.

Japanese Unexamined Patent Application, First Publication, No. 2004-327474 discloses a known three dimensional LSI. The configuration of the three dimensional LSI is suitable for packaging a number of chips on a limited area. The configuration of the three dimensional LSI is also suitable for shortening the wiring distance thereof, thereby realizing a high-density and high-speed device. Particularly, chips for a memory may often have the same size and the same signal terminal array, which is suitable for realizing the stack structure.

The three dimensional LSI may be fabricated as follows. Chips with through-electrodes are formed on a semiconductor wafer. The semiconductor wafer is diced to form separate chips. The chips are stacked over an interposer to form a module. Stacking the chips can be performed by repeating a bonding process, where chips are sequentially bonded to a chip that is placed on a bonder.

Meanwhile, a possible cost reduction is required in manufacturing the three dimensional LSI. Repeating the above-described sequential bonding process needs a long time of using the bonder, thereby causing a high depreciation cost. This means increasing the manufacturing cost.

Japanese Unexamined Patent Application, First Publication, No. 2003-23138 discloses a conventional technique for dicing a semiconductor wafer. A wafer has an array of basic chips. The wafer is diced to form a plurality of memory chips, each of which includes a set of four basic chips.

Japanese Unexamined Patent Application, First Publication, No. 2000-124164 discloses a conventional method of forming a semiconductor device. The method includes the following three processes. The first process is a first separating process for forming gaps between chips over a semiconductor wafer with bump electrodes. The second process is a resin-encapsulation process for performing resin-encapsulation of a chip, while the chip being positioned over a dicing tape. The third process is a second separating process for cutting the encapsulating resin between the chips and the dicing tape, thereby forming separate chips.

Japanese Unexamined Patent Application, First Publication, No. 11-261001 discloses a conventional technique for stacking chips. Namely, this publication discloses a method of forming a three dimensional semiconductor integrated circuit device. This method includes the following four processes. In the first process, there has been prepared a top LSI wafer with trenches, in which vertical interconnections are buried. In the second process, bumps are formed on edges of the vertical interconnections. In the third process, the top LSI wafer is combined with a bottom LSI wafer, while the bumps being interposed between the top and bottom LSI wafers. In the fourth process, an insulating adhesive is injected into a gap between the top and bottom LSI wafers. The LSI wafers may be large scale chips with large area.

Japanese Unexamined Patent Application, First Publication, No. 2003-174116 discloses stacking wafers before dicing the stacked wafers to form separate modules.

In view of the above, it will be apparent to those skilled in the art from this disclosure that there exists a need for an improved apparatus and/or method. This invention addresses this need in the art as well as other needs, which will become apparent to those skilled in the art from this disclosure.

### SUMMARY OF THE INVENTION

Accordingly, it is a primary object of the present invention to provide a method of forming a semiconductor device.

It is another object of the present invention to provide a method of forming a three dimensional LSI, which is suitable for reducing the depreciation cost of a bonder.

It is a further object of the present invention to provide a method of manufacturing a three dimensional LSI, which is suitable for reducing the manufacturing cost.

In accordance with a first aspect of the present invention, a method of forming a semiconductor device includes the following processes. A semiconductor wafer including chips and through electrodes is diced into chip groups. The chip groups are stacked to form a module group.

In accordance with a second aspect of the present invention, a method of forming a semiconductor device includes the following processes. A semiconductor wafer including chips is diced into chip groups. Each of the chip groups includes chips. Non-defective chip groups that are free of any defective chip are selected from the chip groups. The non-defective chip groups are stacked to form a module group. The module group includes modules. Each of the modules includes a stack of chips that are included in the module group. The module group includes a stack of the chip groups.

These and other objects, features, aspects, and advantages of the present invention will become apparent to those skilled in the art from the following detailed descriptions taken in conjunction with the accompanying drawings, illustrating the embodiments of the present invention.

### BRIEF DESCRIPTION OF THE DRAWINGS

Referring now to the attached drawings which form a part of this original disclosure:

FIG. 1 is a schematic perspective view illustrating a three dimensional LSI;

FIG. 2 is a schematic perspective view illustrating a semiconductor device in accordance with a first embodiment of the present invention;

FIG. 3 is a cross sectional elevation view, taken along an A-A′ line of FIG. 2;

FIG. 4 is a fragmentary cross sectional elevation view illustrating structures of through-electrode and connection electrodes shown in FIG. 3;

FIG. 5 is a plan view illustrating a semiconductor wafer including chips; and

FIG. 6 is a flow chart illustrating sequential processes involved in a method of forming a semiconductor device shown in FIGS. 2 and 3.

### DETAILED DESCRIPTION OF THE INVENTION

In accordance with a first aspect of the present invention, a method of forming a semiconductor device includes the following processes. A semiconductor wafer including chips and through electrodes is diced into chip groups. The chip groups are stacked to form a module group.

Stacking the chip groups, each of which includes chips, reduces the number of necessary stacking process as compared to when the chips are stacked. The reduction of the number of necessary stacking process reduces the sharing time of the bonder, thereby improving the throughput.

The chip groups may preferably have a size that is handled by a flip-chip bonder.

The chip groups may preferably have a size of not larger than 40 mm squire.

The module group may include modules. Each of the modules may include a stack of chips that are included in the module group. The module group may include a stack of the chip groups. Each of the chip groups may include chips. The chip groups may be stacked over an interposer that has groups of wirings each corresponding to the modules, thereby forming the module group over the interposer.

The module group may be diced to separate the modules from each other. Each module can more efficiently be formed by stacking the chip groups to form the module group and subsequently dicing the module group into separate modules, as compared to when each module can be obtained by stacking chips.

The method may further include additional processes. At least a defective chip group that includes at least one defective chip and at least one non-defective chip may be selected from the chip groups. The defective chip group may be diced into a plurality of chips that includes the at least one defective chip and the at least one non-defective chip. The non-defective chips are stacked to form a module. Remedy for the non-defective chip or chips included in the defective chip group can be realized by dicing the defective chip group and subsequently stacking the non-defective chips, thereby forming a module. This additional process may improve the yield.

The chips may be memory chips. The memory chips may be DRAMs. The memory chips may often have the same signal terminal array. This configuration can be suitable for stacking the chips to form a semiconductor device.

The above method can reduce the depreciation cost of the bonder. The above method can also reduce the manufacturing cost.

In accordance with a second aspect of the present invention, a method of forming a semiconductor device includes the following processes. A semiconductor wafer including chips is diced into chip groups. Each of the chip groups includes chips. Non-defective chip groups that are free of any defective chip are selected from the chip groups. The non-defective chip groups are stacked to form a module group. The module group includes modules. Each of the modules includes a stack of chips that are included in the module group. The module group includes a stack of the chip groups.

Stacking the chip groups, each of which includes chips, reduces the number of necessary stacking process as compared to when the chips are stacked. The reduction of the number of necessary stacking process reduces the sharing time of the bonder, thereby improving the throughput.

The non-defective chip groups may be stacked by using a flip-chip bonder.

The non-defective chip groups may be stacked over an interposer that has groups of wirings each corresponding to the modules, thereby forming the module group over the interposer.

The method may further include an additional process. The module group is diced to separate the modules from each other. Each module can more efficiently be formed by stacking the chip groups to form the module group and subsequently dicing the module group into separate modules, as compared to when each module can be obtained by stacking chips.

The method may further include additional processes. At least a defective chip group that includes at least one defective chip and at least one non-defective chip is selected from the chip groups. The defective chip group is diced into a plurality of chips that includes the at least one defective chip and the at least one non-defective chip. The non-defective chips are stacked. Remedy for the non-defective chip or chips included in the defective chip group can be realized by dicing the defective chip group and subsequently stacking the non-defective chips, thereby forming a module. This additional process may improve the yield.

The chips may be memory chips. The memory chips may be DRAMs. The memory chips may often have the same signal terminal array. This configuration can be suitable for stacking the chips to form a semiconductor device.

The above method can reduce the depreciation cost of the bonder. The above method can also reduce the manufacturing cost.

Selected embodiments of the present invention will now be described with reference to the drawings. It will be apparent to those skilled in the art from this disclosure that the following descriptions of the embodiments of the present invention are provided for illustration only and not for the purpose of limiting the invention as defined by the appended claims and their equivalents.

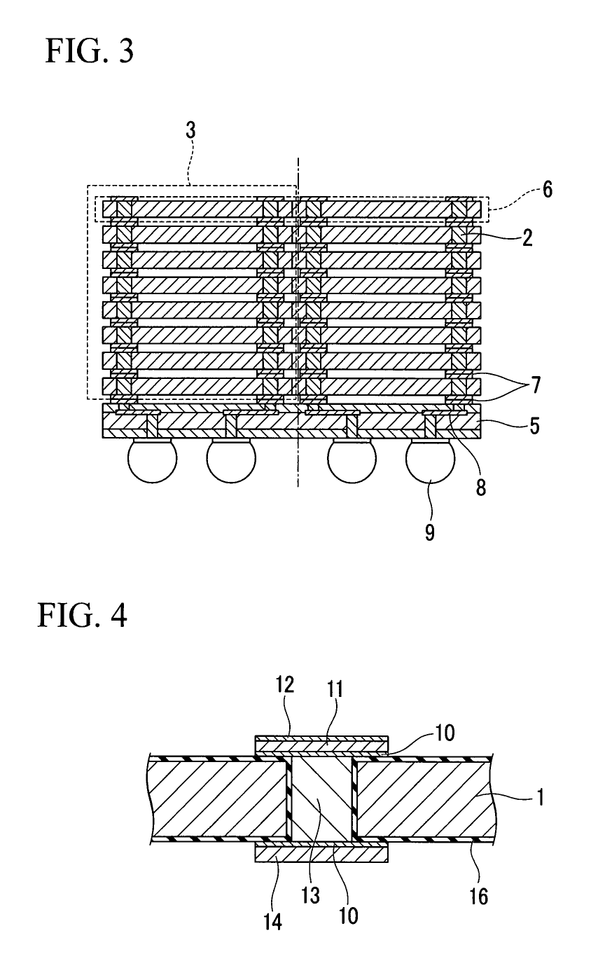

FIG. 2 is a schematic perspective view illustrating a semiconductor device in accordance with a first embodiment of the present invention. FIG. 3 is a cross sectional elevation view, taken along an A-A′ line of FIG. 2.

As shown in FIG. 2, a semiconductor device 17 includes an interposer substrate 5 and a module group 4 that is provided over the interposer substrate 5. The module group 4 may include a stack of chip groups 6 over the interposer substrate 5. As shown in FIGS. 2 and 3, the module group 4 may, for example, include a stack of eight chip groups 6 over the interposer substrate 5, even the number of the stacked chip groups 6 should not be limited to eight.

The chip groups 6 may each have a flat shape. Each chip group 6 includes a plurality of chips. Typically, each chip group 6 may have a size which is suitable for using the normal flip chip bonder to stack the chip groups 6 over the interposer substrate 5. For example, a typical size of each chip group 6 may be, but is not limited to, not greater than 40×40 mm squares. The number of the chips, which is included in each chip group 6, may be decided by taking into account the size of the chip group 6. Namely, each chip group 6 may preferably include the maximum number of the chips, provided that the size of each chip group 6 is not greater than 40×40 mm squares.

The following descriptions will be made in case that each chip group includes four chips 1.

Each chip 1 may be configured to perform as a memory device, while each chip 1 is electrically connected to an external circuit that is not illustrated. In some cases, each chip 1 may be a memory device such as 512 Mbit DRAM (Dynamic Random Access Memory) of 13 mm×10 mm. Typically, memory devices may often have the same size and the same signal terminal array, which makes it easy to realize the stacked structure of the chips. The stacked structure of the chips is suitable for the three-dimensional LSIs that need large capacity.

As shown in FIG. 2, the module group 4 may also include a plurality of modules 3 that includes a stack of eight chips 1. Typically, the module group 4 may include a 2×2 array of four modules 3, each of which includes a stack of eight chips 1. In other words, as described above, the module group 4 may include a stack of eight chip groups 6, each of which includes a 2×2 array of chips 1.

As shown in FIG. 3, each chip 1 has through-electrodes 2 and connection electrodes 7. The chip 1 has an array of through holes in which the through-electrodes 2 are provided so that the through-electrodes 2 penetrate the chip 1. The connection electrodes 7 are provided on opposing edges of each through-electrode 2. The through-electrodes 2 and the connection electrodes 7 in each chip 1 are electrically connected to a built-in circuit in that chip 1. The built-in circuit may be configured to perform signal processing. The through-electrodes 2 and the connection electrodes 7 also provide electrical connection between the chip groups 6. The through-electrodes 2 and the connection electrodes 7 further provide the bottom chip group 6 and the interposer substrate 5.

FIG. 4 is a fragmentary cross sectional elevation view illustrating the structures of the through-electrode 2 and the connection electrodes 7 shown in FIG. 3. The chip 1 has through holes. A silicon oxide film 16 is formed on surfaces of the chip 1 and on the side wall of each through hole. Each through hole is plugged with a conductive material such as copper. The plugged metal such as the plugged copper forms a copper through-hole 13 which acts as the through electrode 2.

A first multi-layered structure is formed on the first edge of the copper through-hole 13 and on an adjacent part of the first surface of the chip 1, wherein the adjacent part is adjacent to the copper through-hole 13. The first multi-layered structure may include plural conductive layers, for example, a Cu-electrode film 10, an Ni-plated film 11, and an Au-plated film 12. The Cu-electrode film 10 contacts with the first edge of the copper through-hole 13. The Ni-plated film 11 is laminated on the Cu-electrode film 10. The Au-plated film 12 is laminated on the Ni-plated film 11. The first multi-layered structure acts as the connection electrode 7 which contacts with the first edge of the copper through-hole 13.

A second multi-layered structure is formed on the second edge of the copper through-hole 13 and on an adjacent part of the second surface of the chip 1, wherein the adjacent part is adjacent to the copper through-hole 13. The second multi-layered structure may include plural conductive layers, for example, another Cu-electrode film 10 and an Su-Ag-plated film 14. The Cu-electrode film 10 contacts with the second edge of the copper through-hole 13. The Su-Ag plated film 14 is laminated on the Cu-electrode film 10. The second multi-layered structure acts as the other connection electrode 7 which contacts with the second edge of the copper through-hole 13.

The through-electrodes 2 may be formed as follows. Through holes are formed in the chip 1 by a known method such as a dry etching process. An insulating film is deposited on the side walls of the through holes and the opposing first and second surfaces of the chip 1. The insulating film may be realized by, but is not limited to, the silicon oxide film 16. The through holes are plugged with Cu, thereby forming the copper through-holes 13 therein.

The connection electrode 7 may be formed as follows. A plating base film is formed on the first edges of the copper through-holes 13 and on the first surface of the chip 1. The plating base film may be realized by, but is not limited to, the Cu-electrode film 10. A film of Ni is pattern-plated to form a Ni-plated film 11 on the Cu-electrode film 10. A film of Au is pattern-plated to form an Au-plated film 12 on the Ni-plated film 11, thereby forming the first multi-layered structure which acts as the connection electrode 7 on the first surface of the chip 1. Another plating base film is formed on the second edges of the copper through-holes 13 and on the second surface of the chip 1. The plating base film may be realized by, but is not limited to, the Cu-electrode film 10. A low-melting metal is pattern-plated to form a low-malting metal film on the Cu-electrode film 10, thereby forming the second multi-layered structure which acts as the connection electrode 7 on the second surface of the chip 1. The low-malting metal film may be realized by, but is not limited to, the Su-Ag-plated film 14.

The interposer substrate 5 is provided to compensate the difference in terminal pitch between the chip 1 and an external circuit that is not illustrated. The interposer substrate 5 may be formed of the same material as the chip 1 in view of the same thermal expansion coefficient. A typical example of a material for the interposer substrate 5 may be silicon. In some cases, the chip 1 and the interposer substrate 5 may be formed of silicon. In other cases, the chip 1 is formed of silicon, while the interposer substrate 5 may be formed of organic resins or ceramics, provided that any known countermeasure is taken to reduce a thermal stress across a connection portion between the interposer substrate 5 and the chip 1.

As shown in FIG. 3, the interposer substrate 5 has buried wirings 8 and solder-balls 9. The buried wirings 5 are electrically connected to the bottom chip 1. The interposer substrate 5 has opposing first and second surfaces. The first surface of the interposer substrate 5 is adjacent to the module group 4. The solder-balls 9 are provided on the second surface of the interposer substrate 5. The solder-balls 9 are electrically connected with the buried wirings 5. The buried wirings 5 extend to the second surface of the interposer substrate 5. The buried wirings 5 are electrically separate from each other and correspond to the modules 3.

Each chip 1 in the module group 4 is electrically connected to the external circuit through the through electrodes 2, the connection electrodes 7, the buried wirings 5, and the solder-balls 9. The three-dimensional stack structure allows a number of chips to be packaged in a limited area. The three-dimensional stack structure also shortens the wiring distance which is suitable for realizing a semiconductor device that has a high density and a high speed performance.

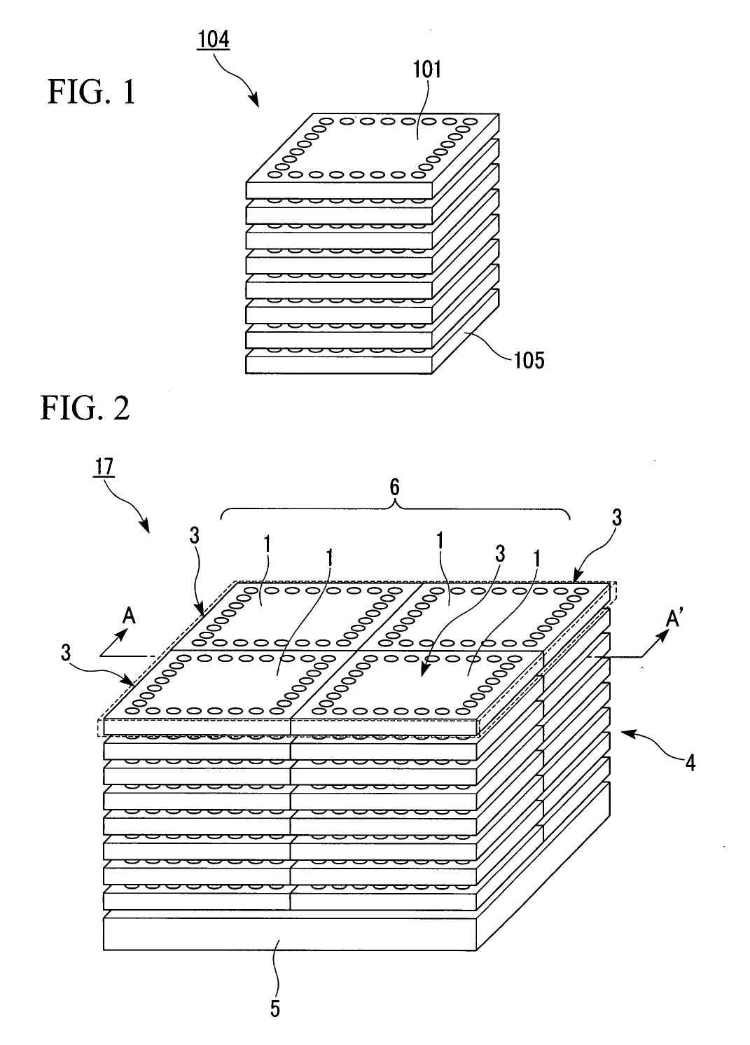

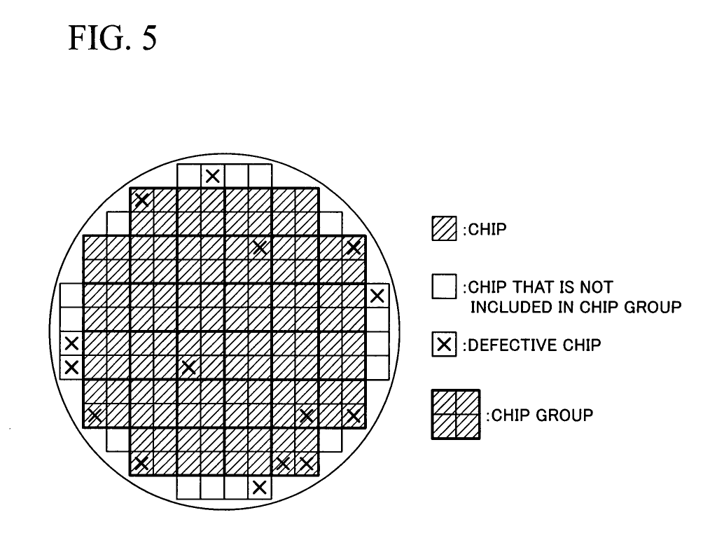

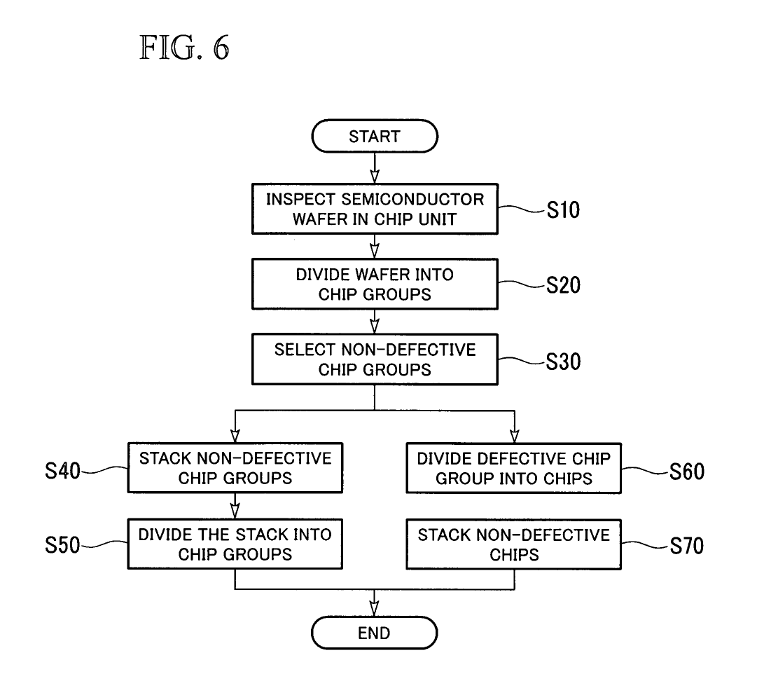

A method of forming the above-described semiconductor device will be described. FIG. 5 is a plan view illustrating a semiconductor wafer including chips 1. FIG. 6 is a flow chart illustrating sequential processes involved in a method of forming the semiconductor device shown in FIGS. 2 and 3. The semiconductor device shown in FIGS. 2 and 3 may be formed by processes S10 through S40. The semiconductor device shown in FIG. 1 may be formed by processes S1 through S50. Processes S60 and S70 may advantageously be performed to improve the yield of the semiconductor device.

In Step S10, as shown in FIG. 5, a plurality of chips 1 is formed on a semiconductor wafer 15. Each chip 1 has through-electrodes 2 and connection electrodes 7 that are not illustrated. Each chip of the semiconductor wafer 15 is inspected to determine whether the chip is defective or non-defective. If the chip is determined as defective, this chip 1 is marked to be discriminated from other non-defective chips 1. In FIG. 5, the mark “X” means the defective chip.

In Step S20, the wafer 15 is diced into chip groups 6 and chips 1. Each chip group 6 includes four chips 1. Chips 1 that are included in the chip groups 6 are marked by hatching. A minority of the chips 1 is positioned near the periphery of the wafer 15 and is difficult to be diced to form the chip groups 6. Thus, the minority of the chips 1 is not subject to the dicing to form the chip groups 6. The chips 1 that are positioned near the periphery of the wafer 15 are subject to the dicing in chip unit. A majority of the chips 1 is subject to the dicing to form the chip groups 6.

In Step S30, chip groups 6, each of which is free of defective chip 1, are determined as non-defective chip groups 6. Chip groups 6, each of which includes at least one defective chip 1, are determined as defective chip groups 6.

In Step S40, the non-defective chip groups 6 are stacked to form a module group 4 over the interposer substrate 5, thereby forming a semiconductor device 17 shown in FIG. 2. The chip group 6 is held by a flip-chip bonder, while the second surface of each chip group 6 faces down. Namely, the second multi-layered structure faces down, which includes the Cu-electrode film 10 and the Su-Ag-plated film 14. The first multi-layered structure faces up, which includes the Cu-electrode film 10, the Ni-plated film 11 and the Au-plated film 12. The first and second multi-layered structures act as the upper and lower connection electrodes 7. The chip group 6 is placed over the other chip group 6 so that the second connection electrodes 7 of the chip group 6 are positioned in contact with the first connection electrodes 7 of the other chip group 6. The Su-Ag-plated film 14 contacts with the Au-plated film 12. Process for stacking the chip groups 6 is performed, while heating the chip groups 6 at about 250° C. The Su-Ag-plated film 14 has a low melting point. Heating the chip groups 6 causes the Su-Ag-plated film 14 to be melted so that the Su-Ag-plated film 14 is thermally bonded with the laminations of the Ni-plated film 11 and the Au-plated film 12. The stacking process is repeated to form a stack of eight chip groups 6. The stack of eight chip groups 6 is bonded with the interposer substrate 5, thereby forming the semiconductor device 17. Namely, the bottom one of the stack of eight chip groups 6 is bonded with the buried wirings 8 of the interposer substrate 8.

Any available bonding methods can be used to bond the chip groups 6 together and bond the bottom chip group 6 to the interposer substrate 5, but the bonding method should not be limited to the above-described method. Available low melting metals other than Su-Ag can be used to perform solder bonding process. Available bonding methods other than the solder bonding method can be used. For example, a conductive resin can be used to perform the bonding process. An ultrasonic bonding using Au-bump can also be used.

In Step S50, the semiconductor device 17 shown in FIG. 2 is divided into a plurality of modules 3. In some cases, the semiconductor device 17 can be diced into four modules 3 along a cutting line shown in FIG. 3. Each module 3 includes the divided interposer substrate 5 and a stack of eight chips 1 over the divided interposer substrate 5 as shown in FIG. 1.

It is of course possible to use the module group 4 as a single device without dividing the module group 4. For example, a controller such as an LSI can be placed on the second surface of the interposer substrate 5 so that the controller controls all chips 1 that are included in the module group 4. In other words, this configuration increases the memory capacity of the memory chips to be controlled under the single controller.

In Step S60, the defective chip group 6 including at least one defective chip 1 is diced into four chips 1. Defective chips 1 and non-defective chips 1 are determined. The defective chips 1 are discarded.

In Step S70, the non-defective chips 1 are stacked. The process for stacking the non-defective chips 1 can be carried out at the same time of the process for stacking the non-defective chip groups 6 in Step S40. Namely, the non-defective chip 1 that is however included in the defective chip group 6 is diced to be separate from the other chips so that the non-defective chip 1 can be used to form the module 3. This may improve the yield.

The following is a table showing approximated costs for the semiconductor devices by comparing the above-described method with the conventional method.

TABLE 1

| | COC | BOB(4) | BOB(9) |
|---|---|---|---|
| Price of Bonder (Yen) | 100,000,000 | 100,000,000 | 100,000,000 |
| TAT Of Stacking 8 Layers | 2 | 2 | 2 |
| (Min.) | | | |
| The Number of Chips | 1 | 4 | 9 |
| In Each Chip Group | | | |
| The Number Of Modules | 12,000 | 48,000 | 108,000 |
| Manufactured (per month) | | | |
| Yield Of Stacking 8 Layers | 1 | 1 | 1 |
| Depreciation Cost | 231 | 58 | 26 |
| Of Bonder (Yen/Module) | | | |
| The Number Of Non- | 0 | 1265 | 2657 |
| defective Chips As Discard | | | |
| The Number Of Non- | 583 | 425 | 425 |
| defective Modules | | | |
| Obtained From 8 Wafers | | | |
| Disposal Loss Of | 0 | 595 | 1,250 |
| Non- defective Chips | | | |
| (Yen/Module) | | | |
| Total Cost For Fabrication | 231 | 653 | 1,276 |
| (Yen/Module) | | | |

| | BOB2(9) | WOW |
|---|---|---|
| Price of Bonder (Yen) | 100,000,000 | 1,000,000,000 |
| TAT Of Stacking 8 Layers (Min.) | 2 | 8 |
| The Number of Chips | 9 | 648 |
| In Each Chip Group | | |
| The Number Of Modules | 108,000 | 1,944,000 |
| Manufactured (per month) | | |
| Yield Of Stacking 8 Layers | 1 | 0.43 |
| Depreciation Cost | 26 | 33 |
| Of Bonder (Yen/Module) | | |
| The Number Of Non-defective | 0 | 2477 |
| Chips As Discard | | |
| The Number Of Non-defective | 648 | 279 |
| Modules Obtained From 8 Wafers | | |
| Disposal Loss Of Non-defective | 0 | 1,774 |
| Chips (Yen/Module) | | |
| Total Cost For Fabrication | 26 | 1,807 |
| (Yen/Module) | | |

“COC” means the known process “chip on chip” for sequentially stacking chips one-by-one, wherein the chips have been diced from a wafer. “BOB” means a process “block on block” for sequentially stacking chip groups or blocks one-by-one prior to dicing the stack into modules, wherein the chip groups or chip blocks have been diced from a wafer. “WOW” means a process “wafer on wafer” for sequentially stacking wafers one-by-one prior to dicing process. “BOB(4)” means the process “block on block” for sequentially stacking non-defective chip groups or blocks one-by-one prior to dicing the stack into modules, wherein each non-defective chip group includes four non-defective chips. “BOB(9)” means a process “block on block” for sequentially stacking non-defective chip groups or blocks one-by-one prior to dicing the stack into modules, wherein each non-defective chip group includes nine non-defective chips. “BOB2(9)” means a modified process “block on block” for sequentially stacking non-defective chip groups or blocks one-by-one prior to dicing the stack into modules, and also for sequentially stacking non-defective chips one-by-one, wherein each non-defective chip group includes nine non-defective chips, and the non-defective chips have been diced from defective chip group. The process “BOB(4)” or the process “BOB(9)” does not stack non-defective chips one-by-one which have been diced from the defective chip group. The processes “BOB” includes the process of Step S50 for dicing the module group 4 into modules even the module group 4 can be used as a single device.

The depreciation cost of the bonder will be discussed. In accordance with the “COC” process, the depreciation cost of the bonder is 231 (Yen/Module) which is a rough-calculated value. Stacking a chip on another chip by the flip-chip bonder will take both a time of holding and positioning the chip and another time of flip-chip bonding. For example, the time of holding and positioning the chip may be 5 seconds, and the time of flip-chip bonding 10 seconds, and thus, the total is 15 seconds, which means the turn around time (TAT). Stacking the eight chips takes 2 minutes. The flip-chip bonder is operated 20 hours day at that TAT, 600 stacks are formed a day. It is assumed that the price of flip-chip bonder is 100,000,000 Yen. The price rate of the flip-chip bonder to product can be approximately calculated by dividing the price of flip-chip bonder by the total number of products produced three years, provided that the flip-chip bonder is operated 20 days per month. The approximately calculated price rate is 231 Yen.

As can be seen from the approximate calculation result, the depreciation cost of the flip-chip bonder increases the cost by about 200 Yen, which reduces the price competitiveness.

The “BOB(4)” process produces four modules by carrying out the bonding processes eight times. Thus, the “BOB(4)” process reduces the depreciation cost of the flip-chip bonder up to one quarter of the depreciation cost when using the “COC” process. Namely, when the “BOB(4)” process is used, the depreciation cost of the flip-chip bonder is 58 Yen per product.

The “BOB(9)” process produces nine modules by carrying out the bonding processes eight times. Thus, the “BOB(9)” process reduces the depreciation cost of the flip-chip bonder up to one ninth of the depreciation cost when using the “COC” process. Namely, when the “BOB(9)” process is used, the depreciation cost of the flip-chip bonder is 26 Yen per product.

The “BOB2(9)” process also produces nine modules by carrying out the bonding processes eight times. Thus, the “BOB2(9)” process reduces the depreciation cost of the flip-chip bonder up to one ninth of the depreciation cost when using the “COC” process. Namely, when the “BOB3(9)” process is used, the depreciation cost of the flip-chip bonder is 26 Yen per product.

Increasing the number of chips that are included in each chip group reduces the depreciation cost of the flip-chip bonder.

In accordance with the “WOW” process, wafers are stacked one-by-one. Positioning and bonding wafers are carried out, even the wafer is much larger in the area than the chip. The maximum size that can be dealt with the flip-chip bonder is approximately 40 mm squares. The flip-chip bonder is incapable of holding and stacking the wafers. Other bonder that is much expensive than the flip-chip bonder is necessary for stacking the wafers. Typically, the rough calculated price of such expensive bonder that is capable of stacking the wafers is 1,000,000,000 Yen. Since the “WOW” process uses the expensive bonder, the depreciation cost of the bonder is 33 Yen even the number of modules to be bonded by a bonding process is larger than the other processes. Namely, the depreciation cost of the bonder of the “WOW” process is larger than the depreciation cost of the bonder of the “BOB(9)” process.

As can be seen from the above calculations, the depreciation cost can be minimized by reducing the number of chips included in each chip group provided that each chip group has a size that can be handled by the flip-chip bonder.

The disposal loss of the non-defective chips will be discussed.

In accordance with the “COC” process or the “BOB2(9)” process, there is no disposal non-defective chip. Namely, the “COC” process or the “BOB2(9)” process provides zero disposal loss of non-defective chips.

In accordance with the “BOB(4)” process, the “BOB(9)” process or the “WOW” process, chip groups or wafers are stacked to form a module group before the module group is diced into a plurality of modules. If the module includes at least one defective chip, then this module is determined as a defective module. Disposal of the defective module including defective and non-defective chips needs. Namely, disposal of non-defective chips should unwillingly be made, thereby reducing the yield.

The above table 1 shows the results of calculation of disposal loss of non-defective chips, under the following conditions. The diameter of a wafer is 300 mm. The size of a chip is 10 mm. 648 chips are obtainable from each wafer. The yield of chips on the wafer is 90%. The price of a chip is 200 Yen. The calculated disposal loss indicates the amount of loss caused by disposal of non-defective chips for each module.

When eight wafers are stacked, then the total number of chips is calculated as 648×8=5184. The calculated number of the non-defective chips is 5184×0.9=approximately 4666. The calculated number of the defective chips is 5184×0.1=approximately 518. The total number of modules obtained in stacking eight chip groups is 648 which are equal to the number of chips that are included in a single wafer.

In accordance with the “BOB(4)” process, each chip group includes four chips. The probability that each chip group is free of any defective chip is calculated as the yield to the fourth power. Namely, the percentage of non-defective chip groups is (0.9)⁴=approximately 0.656. The non-defective chip groups are selected. When eight non-defective chip groups are stacked, then the yield is approximately 0.656. Thus, the number of chips to be used for products is calculated as 5184×0.656=3401. For each module, approximately 425 chips are used for the products. The number of unused chips is calculated as 5184−3401=1783. 1783 chips are subject to disposal. The number of defective chips included in the disposal chips is 518. The number of non-defective chips subject to disposal is 1265. Since each chip price is 200 Yen, the calculated disposal loss is 1265×200=253,000 Yen. In other words, approximately 425 non-defective modules are produced, while the disposal loss of 253,000 Yen of the non-defective chips is caused. Each module can be produced with the disposal loss of 253,000 Yen/425=approximately 595 Yen. The calculated disposal loss of the non-defective chip is approximately 595 Yen.

In accordance with the “BOB(9)” process, the calculated disposal loss of the non-defective chip is approximately 1250 Yen.

In accordance with the “WOW” process, if a module includes at least one defective chip, then this module is determined as a defective module. When eight wafers are stacked, the percentage of non-defective modules is given by the probability of all wafers that are free of any defective chip. The percentage of non-defective modules is calculated as the yield of chips on a wafer to the eighth power. Namely, the percentage of non-defective modules is (0.9)⁸=approximately 0.43. The number of non-defective chips used in the non-defective modules is calculated as 5184×0.43=2229. The number of chips subject to disposal is calculated as 5184−2229=2995. The number of defective chips is calculated as 5184×0.9=approximately 518. The number of non-defective chips subject to disposal is calculated as 2995−518=2477. The calculated disposal loss of the non-defective chip is approximately 1774 Yen.

The “BOB(4)” process and the “BOB(9)” process are effective to reduce the disposal loss as compared to the “WOW” process.

The total cost for fabricating a semiconductor device will be discussed. The total cost for fabrication can be approximately calculated by the sum of the depreciation cost of a bonder and the disposal loss of non-defective chips.

In accordance with the “COC” process or the “BOB2(9)” process, the disposal loss of non-defective chips is zero. In accordance with the “COC” process, the total cost for fabrication is equal to the depreciation cost of a bonder, for example, 231 (Yen/Module).

In accordance with the “BOB2(9)” process, the total cost for fabrication is equal to the depreciation cost of a bonder, for example, 26 (Yen/Module).

In accordance with the “BOB(4)” process, the total cost for fabrication is equal to the sum of the depreciation cost of a bonder and the disposal loss of non-defective chips. The total cost for fabrication is calculated as 58+595=653 (Yen/Module).

In accordance with the “BOB(9)” process, the total cost for fabrication is equal to the sum of the depreciation cost of a bonder and the disposal loss of non-defective chips. The total cost for fabrication is calculated as 26+1250=1276 (Yen/Module).

In accordance with the “WOW” process, the total cost for fabrication is equal to the sum of the depreciation cost of a bonder and the disposal loss of non-defective chips. The total cost for fabrication is calculated as 33+1774=1807 (Yen/Module).

The “BOB(4)” process, the “BOB(9)” process and the “BOB2(9)” process are effective in view of reducing the depreciation cost of a bonder as compared to the “COC” process. The “BOB(4)” process, the “BOB(9)” process and the “BOB2(9)” process are effective in view of reducing the disposal loss of non-defective chips as compared to the “WOW” process. Particularly, the “BOB2(9)” process provides an effective remedy for non-defective chips that are included in the defective chip groups that include defective chips. The remedy ensures that the disposal loss of non-defective chips is zero. The “BOB2(9)” process is effective to reduce the total cost for fabrication as compared to the “COC” process and the “WOW” process.

In accordance with the present invention, a wafer including chips is diced into a plurality of chip groups, each of which includes a plurality of chips before the plurality of chip groups are stacked to form a module group. This method can efficiently stack a number of chips as compared to the conventional method of stacking chips. The defective chip groups, each of which includes both at least one defective chip and at least one non-defective chip, are diced to separate the non-defective chips from the defective chips so that the non-defective chips are stacked to form a module. This can avoid any disposal of non-defective chip, thereby reducing the cost.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A method of forming a semiconductor device, the method comprising:
dicing a semiconductor wafer including chips and through electrodes into chip groups; and
stacking the chip groups to form a module group.

2. The method according to claim 1, wherein the chip groups have a size that is handled by a flip-chip bonder.

3. The method according to claim 1, wherein the chip groups have a size of not larger than 40 mm squire.

4. The method according to claim 1, wherein the module group includes modules, each of the modules includes a stack of chips that are included in the module group, the module group includes a stack of the chip groups, each of the chip groups includes chips, and
stacking the chip groups comprises stacking the chip groups over an interposer that has groups of wirings each corresponding to the modules, thereby forming the module group over the interposer.

5. The method according to claim 4, further comprising:
dicing the module group to separate the modules from each other.

6. The method according to claim 1, further comprising:
selecting, from the chip groups, at least a defective chip group that includes at least one defective chip and at least one non-defective chip;
dicing the defective chip group into a plurality of chips that includes the at least one defective chip and the at least one non-defective chip; and
stacking the non-defective chips.

7. The method according to claim 1, wherein the chips are memory chips.

8. The method according to claim 7, wherein the memory chips are DRAMs.

9. A method of forming a semiconductor device, the method comprising:
dicing a semiconductor wafer including chips into chip groups, each of the chip groups including chips;
selecting non-defective chip groups that are free of any defective chip, from the chip groups; and
stacking the non-defective chip groups to form a module group,
wherein the module group includes modules, each of the modules includes a stack of chips that are included in the module group, and the module group includes a stack of the chip groups.

10. The method according to claim 9, wherein stacking the non-defective chip groups is taken place by using a flip-chip bonder.

11. The method according to claim 9, wherein stacking the non-defective chip groups comprises stacking the non-defective chip groups over an interposer that has groups of wirings each corresponding to the modules, thereby forming the module group over the interposer.

12. The method according to claim 9, further comprising:
dicing the module group to separate the modules from each other.

13. The method according to claim 9, further comprising:
selecting, from the chip groups, at least a defective chip group that includes at least one defective chip and at least one non-defective chip;
dicing the defective chip group into a plurality of chips that includes the at least one defective chip and the at least one non-defective chip; and
stacking the non-defective chips.
